(19) United States
(12) Patent Application Publication
(10) Pub. No.: US 2008/0006819 A1
(43) Pub. Date: Jan. 10, 2008

(54) MOISTURE BARRIER COATINGS FOR ORGANIC LIGHT EMITTING DIODE DEVICES

(75) Inventors: Fred B. McCormick, Maplewood, MN (US); Moses M. David, Woodbury, MN (US); Mark A. Roehrig, Stillwater, MN (US); Manoj Nirmal, St. Paul, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/424,997

(22) Filed: Jun. 19, 2006

(51) Int. Cl. H01L 29/08; H01L 35/24; H01L 51/00

(52) U.S. Cl. 257/40

(57) ABSTRACT

A barrier assembly having a flexible or rigid substrate, an organic electronic device, and one or more layers of diamond-like film. The diamond-like film layers can be used to mount, cover, encapsulate or form composite assemblies for protection of moisture or oxygen sensitive articles such as organic light emitting diode devices, photovoltaic devices, organic transistors, and inorganic thin film transistors. The diamond-like film layers can also provide for edge sealing of adhesive bond lines in the assemblies.

### FIELD OF INVENTION

The present invention relates to barrier films for protection of moisture or oxygen sensitive articles such as OLED devices.

### BACKGROUND

Organic light emitting diode (OLED) devices can suffer reduced output or premature failure when exposed to water vapor or oxygen. Metals and glasses have been used to encapsulate and prolong the life of OLED devices, but metals typically lack transparency and glass lacks flexibility. Intense efforts are underway to find alternative encapsulation materials for OLEDs and other electronic devices. Examples of various types of vacuum processes are described in the patent and technical literature for the formation of barrier coatings. These methods span the range of e-beam evaporation, thermal evaporation, electron-cyclotron resonance plasma-enhanced chemical vapor deposition (PECVD), magnetically enhanced PECVD, reactive sputtering, and others. Barrier performance of the coatings deposited by these methods typically results in a moisture vapor transmission rate (MVTR) in the range from 0.1-5 g/m² day, depending on the specific processes.

Accordingly, a need exists for improved encapsulation of organic electronic devices, such as OLEDs, organic photovoltaic devices (OPVs), and organic transistors, and inorganic electronic devices, such as thin film transistors (including those made using zinc oxide (ZnO), amorphous silicon (a-Si), and low temperature polysilicon (LTPSi)), particularly for those devices on flexible substrates in addition to rigid substrates.

### SUMMARY OF INVENTION

A composite assembly for protection of a moisture or oxygen sensitive article includes a substrate, an organic electronic device overcoated on the substrate, and a diamond-like film layer overcoated on the organic electronic device.

Processes include any method of fabricating this assembly.

The words of orientation such as “atop”, “on”, “uppermost” and the like for the location of various layers in the barrier assemblies or devices refer to the relative position of one or more layers with respect to a horizontal support layer. We do not intend that the barrier assemblies or devices should have any particular orientation in space during or after their manufacture.

The term “overcoated” to describe the position of a layer with respect to a substrate or other element of a barrier assembly, refers to the layer as being atop the substrate or other element, but not necessarily contiguous to either the substrate or the other element.

The term “polymer” refers to homopolymers and copolymers, as well as homopolymers or copolymers that may be formed in a miscible blend, e.g., by coextrusion or by reaction, including, e.g., transesterification. The term “polymer” also includes plasma deposited polymers. The term “copolymer” includes both random and block copolymers. The term “curable polymer” includes both crosslinked and uncrosslinked polymers. The term “crosslinked” polymer refers to a polymer whose polymer chains are joined together by covalent chemical bonds, usually via crosslinking molecules or groups, to form a network polymer. A crosslinked polymer is generally characterized by insolubility, but may be swellable in the presence of an appropriate solvent.

The term a “visible light-transmissive” support, layer, assembly or device means that the support, layer, assembly or device has an average transmission over the visible portion of the spectrum, Tᵥᵢₛ, of at least about 20%, measured along the normal axis.

The term “diamond-like film” (DLF) refers to substantially or completely amorphous glass including carbon and silicon, and optionally including one or more additional components selected from the group including hydrogen, nitrogen, oxygen, fluorine, sulfur, titanium, and copper. Other elements may be present in certain embodiments. The amorphous diamond-like films may contain clustering of atoms to give it a short-range order but are essentially void of medium and long range ordering that lead to micro or macro crystallinity which can adversely scatter radiation having wavelengths of from 180 nanometers (nm) to 800 nm. Specific types of diamond-like films include, diamond-like carbon (DLC), diamond-like glass (DLG), diamond-like nanocomposities (DYLYN), amorphous diamond, tetrahedral amorphous carbon, tetrahedral amorphous hydrogenated carbon, doped diamond-like carbon films, etc.

### BRIEF DESCRIPTION OF THE DRAWINGS

The invention may be more completely understood in the following detailed description of various embodiments of the invention in connection with the accompanying drawings, in which:

FIG. 1 is a schematic view of a barrier assembly;

FIG. 2 is a schematic view of a barrier assembly having multiple layers made from alternating DLF layers and polymer layers;

FIG. 3 is a schematic view of a laminated barrier assembly having multiple layers made from polymers;

FIGS. 4A-4C are diagrams of first embodiments of OLED devices encapsulated with DLF coatings;

FIGS. 5A-5C are diagrams of second embodiments of OLED devices encapsulated with DLF coatings;

FIGS. 6A-6C are diagrams of third embodiments of OLED devices encapsulated with DLF coatings;

FIG. 7 is a diagram of a plasma deposition system for applying DLF coatings; and

FIG. 8 is a schematic diagram of a sample mounting for DLF coating deposition.

### DETAILED DESCRIPTION

An enhanced PECVD process can be used that leads to coatings having superior moisture vapor barrier performance. Excellent barrier performance can be achieved from a SiOCH film formed on a substrate in intimate contact with an electrode utilizing radio frequency (RF) plasma conditions that lead to an oxygen depleted silicon oxide coating under significant energetic ion bombardment. The MVTRs of barrier coatings deposited using this process were less than 0.005 g/m² day measured using ASTM F-1219 at 50° C. Barrier coatings at least 100 nm thick deposited under high self-bias and low pressures (approximately 5-10 mTorr) result in superior moisture vapor transmission rates. The coatings are deposited on an electrode powered using an RF source operating at least 0.1 W/sq.cm of forward power. The vacuum chamber is configured such that these operating conditions result in a very high (>500 V) negative potential on the drum electrode. As a result of ion bombardment from having high substrate bias, the coating formed has very low free volume. The electrode is typically water cooled. A silicon source such as tetra methyl silane (TMS) and oxygen is introduced in quantities such that the resulting coatings are oxygen depleted. Even though the coatings are deficient in oxygen, the coatings have high optical transmission. Nitrogen may be introduced in addition to oxygen to obtain a SiOCNH coating. The SiOCNH coatings also have superior barrier properties.

Therefore, the process conditions that result in better barrier coatings are as follows: (1) barrier coatings are made by an RF PECVD process by locating the substrate on the powered electrode under high self-bias; (2) the CVD process is operated at a very low pressure of less than 50 mTorr, preferably less than 25 mTorr, most preferably less than 10 mTorr to avoid gas phase nucleation and particle formation, and to prevent collisional quenching of ion energy at higher pressures; and (3) the coatings are significantly “oxygen depleted,” meaning that for every Si atom there are less than 1.5 oxygen atoms present in the coating (O/Si atomic ratio <1.5).

The barrier coatings may be used for various types of packaging applications, for example, organic electroluminescent thin films, photovoltaic devices, transistors, and other such devices. Substrates having the barrier coatings may be used in the fabrication of flexible electronic devices such as OLEDs, organic transistors, OPVs, liquid crystal displays (LCD), and other devices. The coatings can also be used to encapsulate the electronic devices directly, and the barrier film could be used as a cover for encapsulating glass or plastic substrate devices. Due to the superior barrier performance of the coatings produced using the described PECVD conditions, such devices could be produced at a lower cost with better performance.

### Exemplary Barrier Assembly Structures

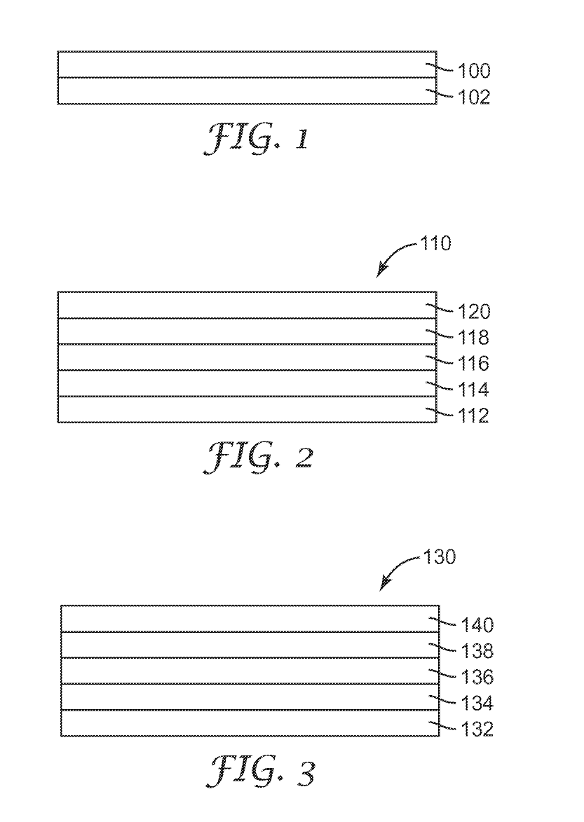

FIG. 1 is a schematic view of a barrier assembly having a coating 100 to reduce or prevent substantial transfer of moisture and oxygen, or other contaminants, to an underlying substrate 102. The assembly can represent any type of article requiring or benefiting from protection from moisture or oxygen, such as the examples provided above. For certain types of electronic or display devices, for example, oxygen and moisture can severely degrade their performance or lifetime, and thus the coating 100 can provide significant advantages in device performance.

FIG. 2 is a schematic view of a laminated barrier assembly 110 having multiple layers made from alternating DLF layers 116, 120 and polymer layers 114, 118 protecting an underlying substrate 112. FIG. 3 is a schematic view of a laminated barrier assembly 130 having multiple layers made from alternating different types of polymer layers, for example alternating polymer layers 136, 140 and polymer layers 134, 138 protecting an underlying substrate 132. In this example, layers 136 and 140 are composed of a first type of polymer, and layers 134 and 138 are composed of a second type of polymer different from the first type of polymer. Any highly crosslinked polymers may be used for the layers, examples of which are provided below. Assembly 130 is thus an all polymer multilayer construction of a barrier assembly, although it can also include other types of layers. Each group of different polymers (e.g., 134 and 136), or combinations of polymers including DLF (e.g., 114 and 116), are referred to as a dyad, and the assembly can include any number of dyads. It can also include various types of optional layers between the dyads, examples of which are provided below.

Assemblies 110 and 130 can include any number of alternating or other layers. Adding more layers may improve the lifetime of the assemblies by increasing their imperviousness to oxygen, moisture, or other contaminants. Use of more or multiple layers may also help cover or encapsulate defects within the layers. The number of layers can be optimized, or otherwise selected, based upon particular implementations or other factors.

### Substrate

Substrates having moisture barrier coatings can include any type of substrate material for use in making a display or electronic device. The substrate can be rigid, for example by using glass or other materials. The substrate can also be curved or flexible, for example by using plastics or other materials. The substrate can be of any desired shape, and it can be transparent or opaque. Particularly preferred supports are flexible plastic materials including thermoplastic films such as polyesters (e.g., PET), polyacrylates (e.g., polymethyl methacrylate), polycarbonates, polypropylenes, high or low density polyethylenes, polyethylene naphthalates, polysulfones, polyether sulfones, polyurethanes, polyamides, polyvinyl butyral, polyvinyl chloride, polyvinylidene difluoride and polyethylene sulfide, and thermoset films such as cellulose derivatives, polyimide, polyimide benzoxazole, and poly benzoxazole.

Other suitable materials for the substrate include chlorotrifluoroethylene-vinylidene fluoride copolymer (CTFE/VDF), ethylene-chlorotrifluoroethylene copolymer (ECTFE), ethylene-tetrafluoroethylene copolymer (ETFE), fluorinated ethylene-propylene copolymer (FEP), polychlorotrifluoroethylene (PCTFE), perfluoroalkyl-tetrafluoroethylene copolymer (PFA), polytetrafluoroethylene (PTFE), polyvinylidene fluoride (PVDF), polyvinyl fluoride (PVF), tetrafluoroethylene-hexafluoropropylene copolymer (TFE/HFP), tetrafluoroethylene-hexafluoropropylene-vinylidene fluoride terpolymer (THV), polychlorotrifluoroethylene (PCTFE), hexafluoropropylene-vinylidene fluoride copolymer (HFP/VDF), tetrafluoroethylene-propylene copolymer (TFE/P), and tetrafluoroethylene-perfluoromethylether copolymer (TFE/PFMe).

Other suitable materials for the substrate include metals and metal alloys. Examples of metals for the substrate include copper, silver, nickel, chromium, tin, gold, indium, iron, zinc, and aluminum. Examples of metal alloys for the substrate include alloys of these listed metals. Another particularly suitable material for the substrate is steel. The metals and metal alloys can be implemented with foils for flexible devices, for example. The metal or metal alloy substrates can include additional materials such as a metal coating on a polymer film.

Alternative substrates include materials having a high glass transition temperature (Tg) barrier, preferably being heat-stabilized, using heat setting, annealing under tension, or other techniques that will discourage shrinkage up to at least the heat stabilization temperature when the support is not constrained. If the support has not been heat stabilized, then it preferably has a Tg greater than that of polymethyl methacrylate (PMMA, Tg=105° C.). More preferably the support has a Tg of at least about 110° C., yet more preferably at least about 120° C., and most preferably at least about 128° C. In addition to heat-stabilized polyethylene terephthalate (HSPET), other preferred supports include other heat-stabilized high Tg polyesters, PMMA, styrene/acrylonitrile (SAN, Tg=110° C.), styrene/maleic anhydride (SMA, Tg=115° C.), polyethylene naphthalate (PEN, Tg=about 120° C.), polyoxymethylene (POM, Tg=about 125° C.), polyvinylnaphthalene (PVN, Tg=about 135° C.), polyetheretherketone (PEEK, Tg=about 145° C.), polyaryletherketone (PAEK, Tg=145° C.), high Tg fluoropolymers (e.g., DYNEON™ HTE terpolymer of hexafluoropropylene, tetrafluoroethylene, and ethylene, Tg=about 149° C.), polycarbonate (PC, Tg=about 150° C.), poly alpha-methyl styrene (Tg=about 175° C.), polyarylate (PAR, Tg=325° C.), polynorborene (PCO, Tg=330° C.), polysulfone (PSul, Tg=about 195° C.), polyphenylene oxide (PPO, Tg=about 200° C.), polyetherimide (PEI, Tg=about 218° C.), polyarylsulfone (PAS, Tg=220° C.), poly ether sulfone (PES, Tg=about 225° C.), polyamideimide (PAI, Tg=about 275° C.), polyimide (Tg=about 300° C.) and polyphthalamide (heat deflection temp of 120° C.). For applications where material costs are important, supports made of HSPET and PEN are especially preferred. For applications where barrier performance is paramount, supports made of more expensive materials may be employed. Preferably the substrate has a thickness of about 0.01 millimeters (mm) to about 1 mm, more preferably about 0.05 mm to about 0.25 mm.

### DLF Layer

Diamond-like film is an amorphous carbon system including a substantial quantity of silicon and oxygen that exhibits diamond-like properties. In these films, on a hydrogen-free basis, there is at least 30% carbon, a substantial amount of silicon (typically at least 25%) and no more than 45% oxygen. The unique combination of a fairly high amount of silicon with a significant amount of oxygen and a substantial amount of carbon makes these films highly transparent and flexible (unlike glass).

Diamond-like thin films may have a variety of light transmissive properties. Depending upon the composition, the thin films may have increased transmissive properties at various frequencies. However, in specific implementations the thin film (when approximately one micron thick) is at least 70% transmissive to radiation at substantially all wavelengths from about 250 nm to about 800 nm and more preferably from about 400 nm to about 800 nm. The extinction coefficient of DLF film is as follows: 70% transmission for a one micron thick film corresponds to an extinction coefficient (k) of less than 0.02 in the visible wavelength range between 400 nm and 800 nm.

Diamond thin films, having significantly different properties from the amorphous diamond-like film of the present invention due to the arrangement and intermolecular bonds of carbon atoms in the specific material, have previously been deposited on substrates. The type and amount of intermolecular bonds are determined by infrared (IR) and nuclear magnetic resonance (NMR) spectra. Carbon deposits contain substantially two types of carbon-carbon bonds: trigonal graphite bonds (sp²) and tetrahedral diamond bonds (sp³). Diamond is composed of virtually all tetrahedral bonds, while diamond-like films are composed of approximately 50% to 90% tetrahedral bonds, and graphite is composed of virtually all trigonal bonds.

The crystallinity and the nature of the bonding of the carbon system determine the physical and chemical properties of the deposit. Diamond is crystalline whereas the diamond-like film is a non-crystalline glassy amorphous material, as determined by x-ray diffraction. Diamond is essentially pure carbon, whereas diamond-like film contains a substantial amount of non-carbon components, including silicon.

Diamond has the highest packing density, or gram atom density (GAD) of any material at ambient pressure. Its GAD is 0.28 gram atoms/cc. Amorphous diamond-like films have a GAD ranging from about 0.20 to 0.28 gram atoms/cc. In contrast, graphite has a GAD of 0.18 gram atoms/cc. The high packing density of diamond-like film affords excellent resistance to diffusion of liquid or gaseous materials. Gram atom density is calculated from measurements of the weight and thickness of a material. The term “gram atom” refers to the atomic weight of a material expressed in grams.

Amorphous diamond-like film is diamond-like because, in addition to the foregoing physical properties that are similar to diamond, it has many of the desirable performance properties of diamond such as extreme hardness (typically 1000 to 2000 kg/mm²), high electrical resistivity (often 10⁹ to 10¹³ ohm-cm), a low coefficient of friction (for example, 0.1), and optical transparency over a wide range of wavelengths (a typical extinction coefficient of about between 0.01 and 0.02 in the 400 nm to 800 nm range).

Diamond films also have some properties which, in many applications, make them less beneficial than amorphous diamond-like films. Diamond films usually have grain structures, as determined by electron microscopy. The grain boundaries are a path for chemical attack and degradation of the substrates, and also cause scattering of actinic radiation. Amorphous diamond-like film does not have a grain structure, as determined by electron microscopy, and is thus well suited to applications wherein actinic radiation will pass through the film. The polycrystalline structure of diamond films causes light scattering from the grain boundaries.

In creating a diamond-like film, various additional components can be incorporated into the basic SiOCH composition. These additional components can be used to alter and enhance the properties that the diamond-like film imparts to the substrate. For example, it may be desirable to further enhance the barrier and surface properties.

The additional components may include one or more of hydrogen (if not already incorporated), nitrogen, fluorine, sulfur, titanium, or copper. Other additional components may also be of benefit. The addition of hydrogen promotes the formation of tetrahedral bonds. The addition of fluorine is particularly useful in enhancing barrier and surface properties of the diamond-like film, including the ability to be dispersed in an incompatible matrix. The addition of nitrogen may be used to enhance resistance to oxidation and to increase electrical conductivity. The addition of sulfur can enhance adhesion. The addition of titanium tends to enhance adhesion as well as diffusion and barrier properties.

These diamond-like materials may be considered as a form of plasma polymers, which can be deposited on the assembly using, for example, a vapor source. The term “plasma polymer” is applied to a class of materials synthesized from a plasma by using precursor monomers in the gas phase at low temperatures. Precursor molecules are broken down by energetic electrons present in the plasma to form free radical species. These free radical species react at the substrate surface and lead to polymeric thin film growth. Due to the non-specificity of the reaction processes in both the gas phase and the substrate, the resulting polymer films are highly cross-linked and amorphous in nature. This class of materials has been researched and summarized in publications such as the following: H. Yasuda, “Plasma Polymerization,” Academic Press Inc., New York (1985); R.d'Agostino (Ed), “Plasma Deposition, Treatment & Etching of Polymers,” Academic Press, New York (1990); and H. Biederman and Y. Osada, “Plasma Polymerization Processes,” Elsever, N.Y. (1992).

Typically, these polymers have an organic nature to them due to the presence of hydrocarbon and carbonaceous functional groups such as CH₃, CH₂, CH, Si—C, Si—CH₃, Al—C, Si—O—CH₃, etc. The presence of these functional groups may be ascertained by analytical techniques such as IR, nuclear magnetic resonance (NMR) and secondary ion mass (SIMS) spectroscopies. The carbon content in the film may be quantified by electron spectroscopy for chemical analysis (ESCA).

Not all plasma deposition processes lead to plasma polymers. Inorganic thin films are frequently deposited by PECVD at elevated substrate temperatures to produce thin inorganic films such as amorphous silicon, silicon oxide, silicon nitride, aluminum nitride, etc. Lower temperature processes may be used with inorganic precursors such as silane (SiH₄) and ammonia (NH₃). In some cases, the organic component present in the precursors is removed in the plasma by feeding the precursor mixture with an excess flow of oxygen. Silicon rich films are produced frequently from tetramethyldisiloxane (TMDSO)-oxygen mixtures where the oxygen flow rate is ten times that of the TMDSO flow. Films produced in these cases have an oxygen to silicon ratio of about 2, which is near that of silicon dioxide.

The plasma polymer layer of this invention is differentiated from other inorganic plasma deposited thin films by the oxygen to silicon ratio in the films and by the amount of carbon present in the films. When a surface analytic technique such as ESCA is used for the analysis, the elemental atomic composition of the film may be obtained on a hydrogen-free basis. Plasma polymer films of the present invention are substantially sub-stoichiometric in their inorganic component and substantially carbon-rich, depicting their organic nature. In films containing silicon for example, the oxygen to silicon ratio is preferably below 1.8 (silicon dioxide has a ratio of 2.0), and most preferably below 1.5 as in the case of DLF, and the carbon content is at least about 10%. Preferably, the carbon content is at least about 20% and most preferably at least about 25%. Furthermore, the organic siloxane structure of the films may be detected by IR spectra of the film with the presence of Si—CH₃ groups at 1250 cm⁻¹ and 800 cm⁻¹, and by secondary ion mass spectroscopy (SIMS).

One advantage of DLF coatings or films is their resistance to cracking in comparison to other films. DLF coatings are inherently resistant to cracking either under applied stress or inherent stresses arising from manufacture of the film, as described in U.S. patent application Ser. No. 11/185,078, entitled “Moisture Barrier Coatings,” and filed Jul. 20, 2005, which is incorporated herein by reference as if fully set forth.

### Polymer Layers

The polymer layers used in the multilayer stack of the barrier assemblies are preferably crosslinkable. The crosslinked polymeric layer lies atop the substrate or other layers, and it can be formed from a variety of materials. Preferably the polymeric layer is crosslinked in situ atop the underlying layer. If desired, the polymeric layer can be applied using conventional coating methods such as roll coating (e.g., gravure roll coating) or spray coating (e.g., electrostatic spray coating), then crosslinked using, for example, ultraviolet (UV) radiation. Most preferably the polymeric layer is formed by flash evaporation, vapor deposition and crosslinking of a monomer as described in the present specification. Volatilizable (meth)acrylate monomers are preferred for use in such a process, with volatilizable acrylate monomers being especially preferred. Preferred (meth)acrylates have a molecular weight in the range of about 150 to about 600, more preferably about 200 to about 400. Other preferred (meth)acrylates have a value of the ratio of the molecular weight to the number of acrylate functional groups per molecule in the range of about 150 to about 600 g/mole/(meth)acrylate group, more preferably about 200 to about 400 g/mole/(meth)acrylate group. Fluorinated (meth)acrylates can be used at higher molecular weight ranges or ratios, e.g., about 400 to about 3000 molecular weight or about 400 to about 3000 g/mole/(meth)acrylate group. Coating efficiency can be improved by cooling the support. Particularly preferred monomers include multifunctional (meth)acrylates, used alone or in combination with other multifunctional or mono functional (meth)acrylates, such as hexanediol diacrylate, ethoxyethyl acrylate, phenoxyethyl acrylate, cyanoethyl (mono)acrylate, isobornyl acrylate, isobornyl methacrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl (meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propylated trimethylol propane triacrylate, tris(2-hydroxyethyl)isocyanurate triacrylate, pentaerythritol triacrylate, phenylthioethyl acrylate, naphthloxyethyl acrylate, IRR-214 cyclic diacrylate from CYTEC INDUSTRIES, INC., epoxy acrylate RDX80095 from Rad-Cure Corporation, and mixtures thereof. A variety of other curable materials can be included in the crosslinked polymeric layer, e.g., vinyl ethers, vinyl naphthylene, acrylonitrile, and mixtures thereof.

Alternative materials for the polymer layers include materials having a Tg greater than or equal to that of HSPET. A variety of alternative polymer materials can be employed. Volatilizable monomers that form suitably high Tg polymers are especially preferred. Preferably the alternative polymer layer has a Tg greater than that of PMMA, more preferably a Tg of at least about 110° C., yet more preferably at least about 150° C., and most preferably at least about 200° C. Especially preferred monomers that can be used to form this layer include urethane acrylates (e.g., CN-968, Tg=about 84° C. and CN-983, Tg=about 90° C., both commercially available from Sartomer Co.), isobornyl acrylate (e.g., SR-506, commercially available from Sartomer Co., Tg=about 88° C.), dipentaerythritol pentaacrylates (e.g., SR-399, commercially available from Sartomer Co., Tg=about 90° C.), epoxy acrylates blended with styrene (e.g., CN-120S80, commercially available from Sartomer Co., Tg=about 95° C.), di-trimethylolpropane tetraacrylates (e.g., SR-355, commercially available from Sartomer Co., Tg=about 98° C.), diethylene glycol diacrylates (e.g., SR-230, commercially available from Sartomer Co., Tg=about 100° C.), 1,3-butylene glycol diacrylate (e.g., SR-212, commercially available from Sartomer Co., Tg=about 101° C.), pentaacrylate esters (e.g., SR-9041, commercially available from Sartomer Co., Tg=about 102° C.), pentaerythritol tetraacrylates (e.g., SR-295, commercially available from Sartomer Co., Tg=about 103° C.), pentaerythritol triacrylates (e.g., SR-444, commercially available from Sartomer Co., Tg=about 103° C.), ethoxylated (3) trimethylolpropane triacrylates (e.g., SR-454, commercially available from Sartomer Co., Tg=about 103° C.), ethoxylated (3) trimethylolpropane triacrylates (e.g., SR-454HP, commercially available from Sartomer Co., Tg=about 103° C.), alkoxylated trifunctional acrylate esters (e.g., SR-9008, commercially available from Sartomer Co., Tg=about 103° C.), dipropylene glycol diacrylates (e.g., SR-508, commercially available from Sartomer Co., Tg=about 104° C.), neopentyl glycol diacrylates (e.g., SR-247, commercially available from Sartomer Co., Tg=about 107° C.), ethoxylated (4) bisphenol a dimethacrylates (e.g., CD-450, commercially available from Sartomer Co., Tg=about 108° C.), cyclohexane dimethanol diacrylate esters (e.g., CD-406, commercially available from Sartomer Co., Tg=about 110° C.), isobornyl methacrylate (e.g., SR-423, commercially available from Sartomer Co., Tg=about 110° C.), cyclic diacrylates (e.g., IRR-214, commercially available from Cytec Industries, Inc., Tg=about 208° C.) and tris (2-hydroxy ethyl) isocyanurate triacrylate (e.g., SR-368, commercially available from Sartomer Co., Tg=about 272° C.), acrylates of the foregoing methacrylates and methacrylates of the foregoing acrylates.

### Other Optional Layers, Coatings, and Treatments

Optional layers can include “getter” or “desiccant” layers functionally incorporated within or adjacent to the barrier coating; examples of such layers are described in copending U.S. patent application Ser. Nos. 10/948,013 and 10/948,011, which are incorporated herein by reference as if fully set forth. Getter layers include layers with materials that absorb or deactivate oxygen, and desiccant layers include layers with materials that absorb or deactivate water.

Optional layers can include encapsulating films, for example barrier layers, optical films, or structured films. The optical film can include, for example, a light extracting film, a diffuser, or a polarizer. The structured film can include films having microstructured (micron-scaled) features such as prisms, grooves, or lenslets.

The optional barrier layers include one or more inorganic barrier layers. The inorganic barrier layers, when multiple such layers are used, do not have to be the same. A variety of inorganic barrier materials can be employed. Preferred inorganic barrier materials include metal oxides, metal nitrides, metal carbides, metal oxynitrides, metal oxyborides, and combinations thereof, e.g., silicon oxides such as silica, aluminum oxides such as alumina, titanium oxides such as titania, indium oxides, tin oxides, indium tin oxide (“ITO”), tantalum oxide, zirconium oxide, niobium oxide, boron carbide, tungsten carbide, silicon carbide, aluminum nitride, silicon nitride, boron nitride, aluminum oxynitride, silicon oxynitride, boron oxynitride, zirconium oxyboride, titanium oxyboride, and combinations thereof. Indium tin oxide, silicon oxide, aluminum oxide and combinations thereof are especially preferred inorganic barrier materials. ITO is an example of a special class of ceramic materials that can become electrically conducting with the proper selection of the relative proportions of each elemental constituent.

The inorganic barrier layers, when incorporated into the assembly, preferably are formed using techniques employed in the film metallizing art such as sputtering (e.g., cathode or planar magnetron sputtering), evaporation (e.g., resistive or electron beam evaporation), chemical vapor deposition, plating and the like. Most preferably the inorganic barrier layers are formed using sputtering, e.g., reactive sputtering. Alternatively, they can be formed atomic layer deposition, which can help to seal pin holes in the barrier coatings.

Enhanced barrier properties have been observed when the inorganic layer is formed by a high energy deposition technique such as sputtering compared to lower energy techniques such as conventional chemical vapor deposition processes. Without being bound by theory, it is believed that the enhanced properties are due to the condensing species arriving at the substrate with greater kinetic energy, leading to a lower void fraction as a result of compaction. The smoothness and continuity of each inorganic barrier layer and its adhesion to the underlying layer can be enhanced by pretreatments (e.g., plasma pretreatment) such as those described above.

The barrier assemblies can also have a protective polymer topcoat. If desired, the topcoat polymer layer can be applied using conventional coating methods such as roll coating (e.g., gravure roll coating), spray coating (e.g., electrostatic spray coating), or plasma deposition. A pretreatment (e.g., plasma pretreatment) may be used prior to formation of the topcoat polymer layer. The desired chemical composition and thickness of the topcoat polymer layer will depend in part on the nature and surface topography of the underlying layer(s), the hazards to which the barrier assembly might be exposed, and applicable device requirements. The topcoat polymer layer thickness preferably is sufficient to provide a smooth, defect-free surface that will protect the underlying layers from ordinary hazards.

### General Techniques for Coating of Polymer Layers

The polymer layers can be formed by applying a layer of a monomer or oligomer to the substrate and crosslinking the layer to form the polymer in situ, e.g., by flash evaporation and vapor deposition of a radiation-crosslinkable monomer, followed by crosslinking using, for example, an electron beam apparatus, UV light source, electrical discharge apparatus or other suitable device. Coating efficiency can be improved by cooling the support. The monomer or oligomer can also be applied to the substrate using conventional coating methods such as roll coating (e.g., gravure roll coating), spray coating (e.g., electrostatic spray coating), or plasma deposition, then crosslinked as set out above. The polymer layers can also be formed by applying a layer containing an oligomer or polymer in solvent and drying the thus-applied layer to remove the solvent. Most preferably, the polymer layers are formed by flash evaporation and vapor deposition followed by crosslinking in situ.

### Manufacturing Process

A roll-to-roll manufacture (web process) to make barrier assemblies is described in U.S. Pat. No. 5,888,594, incorporated herein by reference. In addition to a web process, barrier assemblies can be made in a batch process such as those described below in the Examples.

### Encapsulation of OLED Devices with DLF Coatings

Organic electronic devices such as OLED devices, OPVs, and organic transistors are typically sensitive to oxygen and moisture present in the ambient atmosphere. Embodiments of the present invention include the use of an enhanced PECVD process that leads to DLF coatings having superior moisture vapor barrier performance. In one particular embodiment, SiOCH barrier coatings are deposited directly onto a bare OLED device with at least no substantial degradation of device performance induced by the deposition process. In a second embodiment, barrier coatings are deposited directly onto an OLED device previously encapsulated with a protective film that is in intimate contact with the OLED structure with at least no substantial degradation of device performance induced by the deposition process. In a third embodiment, barrier coatings are deposited directly onto an OLED device previously encapsulated with a protective film that is not in intimate contact with the OLED structure with at least no substantial degradation of device performance induced by the deposition process. In further embodiments, the barrier coatings can also be applied to the surface of the device substrate opposite that which carries the device.

An OLED is typically a thin film structure formed on a substrate such as glass or transparent plastic. A light-emitting layer of an organic electroluminescent (EL) material and optional adjacent semiconductor layers are located between a cathode and an anode. The EL material can be sandwiched or interdigitated, for example, between the cathode and anode. As an alternative to a conventional OLED device, a light-emitting electrochemical cell may be used, an example of which is described in U.S. Pat. No. 5,682,043, which is incorporated herein by reference. The semiconductor layers may be either hole injection (positive charge) or electron injection (negative charge) layers and also comprise organic materials. The material for the light-emitting layer may be selected from many organic EL materials. The light emitting organic layer may itself include multiple sublayers, each comprising a different organic EL material. Examples of the organic EL materials include the following: vapor deposited small molecule materials; and solution coated light emitting polymers and small molecules applied by spin coating, inkjet printing, or screen printing. The organic EL material can be transferred to a receptor by laser induced thermal imaging (LITI) to make a LITI patterned device. The OLED devices can include passive matrix OLEDs or active matrix OLEDs. The devices can also include other components for use in driving them such as conductive leads and antennas.

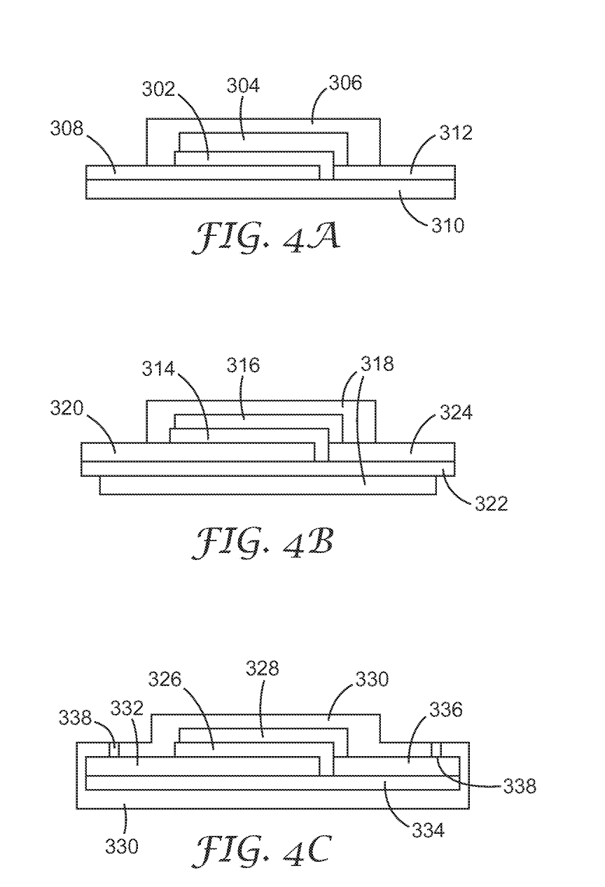

FIGS. 4A-4C, 5A-5C, and 6A-6C show diagrams of various exemplary embodiments of barrier assemblies. FIG. 4A illustrates a device having, with the construction shown, organics 302, a cathode 304, DLF 306, an anode and lead 308, a substrate 310, and a cathode lead 312. FIG. 4B illustrates a device having, with the construction shown, organics 314, a cathode 316, DLF 318, an anode and lead 320, a substrate 322, and a cathode lead 324. FIG. 4C illustrates a device having, with the construction shown, organics 326, a cathode 328, DLF 330, an anode and lead 332, a substrate 334, a cathode lead 336, and contact vias 338. The vias can provide for electrical connection to the cathode and anode leads or other electrodes using, for example, vias conductive adhesives, silver ink, or soldering.

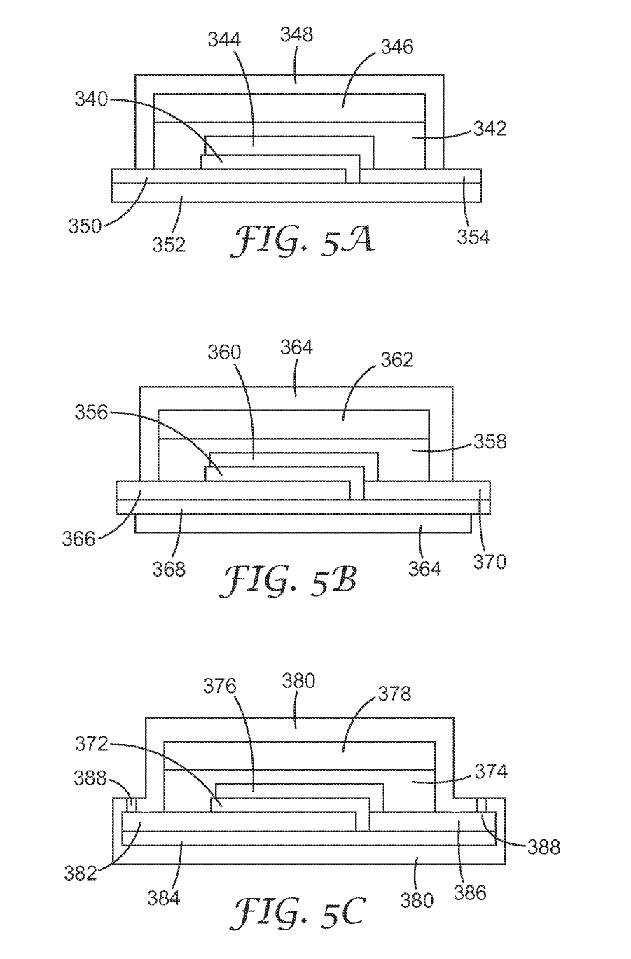

FIG. 5A illustrates a device having, with the construction shown, organics 340, an adhesive 342, a cathode 344, a cover film 346, DLF 348, an anode and lead 350, a substrate 352, and a cathode 354. FIG. 5B illustrates a device having, with the construction shown, organics 356, an adhesive 358, a cathode 360, a cover film 362, DLF 364, an anode and lead 366, a substrate 368, and a cathode lead 370. FIG. 5C illustrates a device having, with the construction shown, organics 372, an adhesive 374, a cathode 376, a cover film 378, DLF 380, an anode and lead 382, a substrate 384, a cathode lead 386, and contact vias 388.

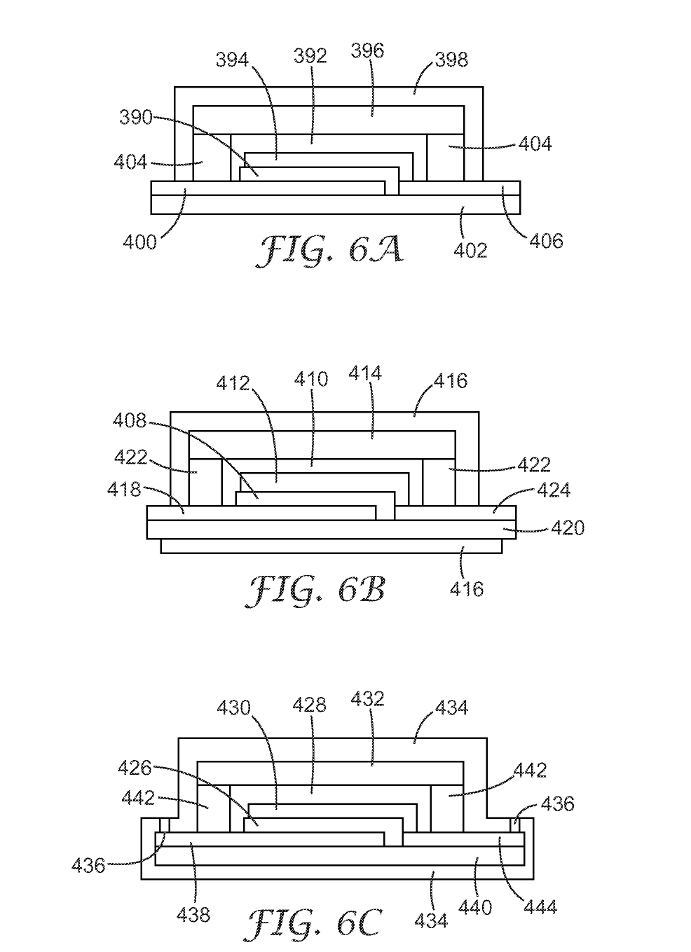

FIG. 6A illustrates a device having, with the construction shown, organics 390, an open space 392, cathode 394, cover film 396, DLF 398, an anode and lead 400, a substrate 402, an adhesive 404, and a cathode lead 406. FIG. 6B illustrates a device having, with the construction shown, organics 408, an open space 410, a cathode 412, a cover film 414, DLF 416, an anode and lead 418, a substrate 420, an adhesive 422, and a cathode lead 424. FIG. 6C illustrates a device having, with the construction shown, organics 426, an open space 428, a cathode 430, a cover film 432, DLF 434, contact vias 436, an anode and lead 438, a substrate 440, an adhesive 442, and a cathode lead 444.

In FIGS. 4A-4C, 5A-5C, and 6A-6C, the recited elements can be implemented with, for example, the following: the organics can include an OLED or any organic electronic device; the substrates can include any of those substrate materials identified above including flexible or rigid materials; the anode, cathode, and contact vias (or other types of electrodes such as a source, drain, and gate for a transistor) can include a metal or any conductive element; the adhesive can include any material capable of adhering together two or more components such as an optical adhesive; the cover film can include any material such as a polymer layer or a film such as PET as previously described for substrates and rigid materials such as glass and metal; and the DLF can include a film of the DLF as described above or other DLF. Also, the encapsulating or protective layers of the devices shown in FIGS. 6A-6C, 7A-7C, and 8A-8C can be repeated to form any number of dyads, and the devices can alternatively include additional layers such as those identified above.

In lieu of contact vias, electrical contacts may be made by interleaving conductive paths between layers of encapsulating films. Such a contact can be formed by first coating through, for example, a shadow mask a substantial portion, typically more than one half, of the organic electronic device with a thin film encapsulant such that a portion of a device electrode remains exposed. A conductive film, such as a metal or transparent conductive oxide, is then deposited through a different mask such that contact is made with the exposed electrode and a portion of the conductive film is disposed on the initial encapsulation film. A second encapsulation film is then deposited such that the exposed portion of the device is covered as well as a portion of the first encapsulation film and conductive film. The end result is an organic electronic device covered by a thin film encapsulant and a conductive path from an electrode to the exterior of the device.

This type of encapsulation may be particularly useful for direct-drive OLED solid state lighting and signage applications as minimal patterning of the bottom electrode is required. Multiple layers with interleaved conductors may be deposited, and conductive paths to multiple electrodes on a single substrate may be established. The thin film encapsulants may include DLF, sputtered oxides, plasma polymerized films, thermally deposited materials such as SiO and GeO, and polymer/barrier multilayers.

It is also possible to combine the various embodiments of the present invention. For example, an OLED device can be directly encapsulated with DLF as illustrated in the embodiments shown in FIGS. 4A-4C, followed by lamination of a protective film and a second layer of DLF; in essence, this combines embodiments shown in FIGS. 4A-4C and 5A-5C.

The barrier coatings of embodiments of the present invention provide for several advantageous characteristics. The barrier coatings are hard and abrasion resistant, provide improved moisture and oxygen protection, may be single layers or multiple layers, have good optical properties, and can provide a way to edge-seal adhesive bond lines as illustrated in FIGS. 4C, 5C, and 6C. The barrier coatings may be applied to flexible and rigid devices or substrates.

Direct encapsulation of OLEDs provides for a process that can be carried out at high speed. The DLF deposition process is rapid; 30 Å/second deposition rates have been shown and higher rates are possible. The DLF deposition process may provide for single layer direct encapsulation, although multilayers may be desirable in some cases. The ion enhanced plasma deposition process, as described above and in the Examples, does not damage the OLED device layers. However, stresses in the deposited DLF coatings may cause delamination of the OLED device architecture in some instances. This situation may be avoided by placing protective and/or stress relieving coatings on top of the OLED prior to the DLF encapsulation. Protective coatings could include, for example, metal films or ceramic films such as silicon monoxide or boron oxide. Boron oxide would also serve as a desiccant layer. Metallic protective films may require an insulating underlayer to avoid undesirable electrical shorting between individual emissive areas on a device. Stress relieving coatings can also include organic coatings on top of the OLED prior to DLF encapsulation.

One method of applying stress reducing coatings includes depositing layers of deformable materials over top of the OLED prior to DLF deposition. For example, copper phthalocyanine, AlQ, MoS₂, or organic glass-like materials can be vapor deposited in vacuum from heated crucibles as the last step in the OLED device fabrication process. Stresses in the subsequent DLF layers can be relieved by relaxation, deformation, or delamination of these layers, thereby preventing delamination of the OLED device layers.

Another method of applying protective and/or stress relieving coatings includes adhesively laminating a cover film onto the OLED. The cover film could be a transfer adhesive layer, such as a Thermobond™ hot melt adhesive or it could be PET, PEN, or the like, or a barrier film such as ultrabarrier film coated with an adhesive layer. An example of an embodiment having strain relief includes the construction shown in FIG. 5A without the cover film 346. Ultrabarrier films include multilayer films made, for example, by vacuum deposition of two inorganic dielectric materials sequentially in a multitude of layers on a glass or other suitable substrate, or alternating layers of inorganic materials and organic polymers, as described in U.S. Pat. Nos. 5,440,446; 5,877,895; and 6,010,751, all of which are incorporated herein by reference.

Bare adhesive or PET and PEN film layers may provide sufficient protection to allow an OLED device to be transferred under ambient conditions to a DLF encapsulation tool. Ultrabarrier films may provide sufficient encapsulation to enable long device lifetimes. Depositing DLF coatings over top of the encapsulation film seals the edges of the adhesive bond lines as well as provides an additional barrier coating on the surface of the encapsulating film. Substrates can also include non-barrier substrate materials, in which case the DLF can also be used to encapsulate the substrate as shown in FIGS. 4B, 4C, 5B, 5C, 6B, and 6C.

A further advantage of the DLF deposition process is that it has been demonstrated in a roll-to-roll format. Thus, the DLF encapsulation method, including the use of protective stress relief, and/or cover film layers, is well suited to an OLED web manufacturing process. The process may be used on both top emitting and bottom emitting OLED device architectures.

Embodiments of the present invention will now be described with reference to the following non-limiting examples.

### EXAMPLE 1

Table 1 provides a description of abbreviations used in the present specification.

TABLE 1

| Abbreviation | Description/Commercial Source |
|---|---|
| NPD | N,N′-bis(3-naphthalen-2-yl)-N,N′-bis(phenyl)benzidine |
| | available from H.W. Sands Corp, Jupiter, FL |
| AlQ | Tris(8-hydroxyquinoline) aluminum available |
| | from H.W. Sands Corp, Jupiter, FL |
| C545T | Coumarin available from Eastman Kodak Co., Rochester, |
| | NY as Coumarin 545T |
| FTCNQ | Tetrafluoro-tetracyanoquinodimethane available from |
| | Tokyo Kasei Kogyo Co., Tokyo, Japan |
| LiF | Lithium fluoride, 99.85%, available from Alfa Aesar, |
| | Ward Hill, MA |
| Al | Puratronic aluminum shots, 99.999%, available from Alfa |
| | Aesar, Ward Hill, MA |
| MTDATA | 4,4′,4″-tris(N-3-methylphenyl-N- |
| | phenylamino)triphenylamine, sublimed, available |
| | from H.W. Sands Corp., Jupiter, FL |
| Ag | Premion silver shot, 99.999% available from Alfa Aesar, |
| | Ward Hill, MA |
| Cr | Puratronic chromium pieces, 99.997% available from |
| | Alfa Aesar, Ward Hill, MA |
| TMS | Tetramethylsilane, NMR grade, 99.9% available from |
| | Sigma-Aldrich, Milwaukee, WI |
| SiO | Silicon monoxide, 99.9% available from Alfa Aesar, |
| | Ward Hill, MA |
| ITO | Indium tin oxide |

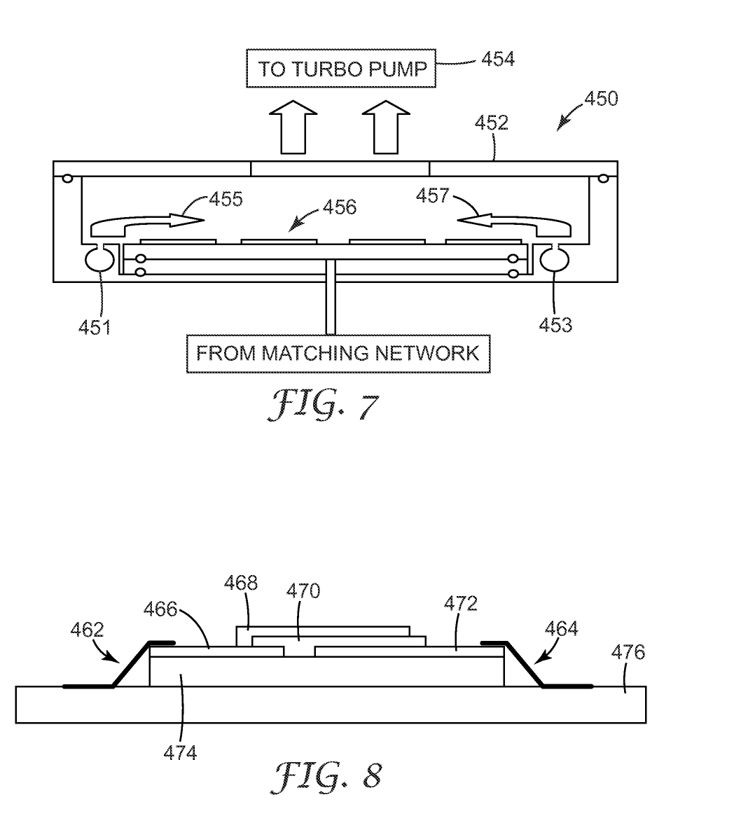

As shown in FIG. 7, a plasma deposition system 450 was used for the deposition of the DLF onto devices 456. System 450 comprises an aluminum chamber 452 containing a 12″×12″ bottom electrode with the chamber acting as the counter-electrode. The spacing between the powered electrode and the grounded electrode is three inches. Because of the larger surface area of the grounded electrode, the system may be considered to be asymmetric, resulting in a large sheath potential at the powered electrode on which the substrates to be coated are placed. The chamber is pumped by a pumping system 454, which comprises a turbomolecular pump (Pfeiffer Model No. TPH510) backed by a mechanical pump (Edwards Model No. 80). A gate valve serves to isolate the chamber from the pumping system when the chamber is vented.

Process gases 455 and 457 are metered through mass flow controllers (Brooks Model No. 5850 S) and blended in a manifold before they are introduced into the chamber through gun-drilled holes 451 and 453 parallel to the electrode and linked into the chamber by a multitude of smaller (0.060″ diameter) holes spaced one inch apart. Pneumatic valves serve to isolate the flow controllers from the gas/vapor supply lines. The process gases, oxygen (ultrahigh purity 99.99%, from Scott Specialty Gases) and tetramethylsilane (TMS NMR grade, 99.9%, from Sigma Aldrich) are stored remotely in gas cabinets and piped to the mass flow controllers by 0.25″ (diameter) stainless steel gas lines. The typical base pressure in the chamber is below 1×10⁻⁵ Torr based on the size and type of the pumping system. Pressure in the chamber is measured by a 1 Torr capacitance manometer (type 390 from MKS Instruments).

The plasma is powered by a 13.56 MHz radio frequency power supply (Advanced Energy, Model RFPP-RF10S) and an impedance matching network (Advanced Energy, Model RFPP-AM20). The AM-20 impedance network was modified by changing the load coil and the shunt capacitance to suit the plasma system constructed. The impedance matching network serves to automatically tune the plasma load to the 50 ohm impedance of the power supply to maximize power coupling. Under typical conditions, the reflected power is less than 2% of the incident power.

A silicon source such as tetramethylsilane (TMS from Sigma Aldrich) and oxygen is introduced in quantities such that the resulting coatings are oxygen depleted. Even though the coatings are deficient in oxygen, the coatings have high optical transmission. Nitrogen may be introduced in addition to oxygen to obtain a SiOCNH coating. The SiOCNH coatings also have superior barrier properties.

Bottom emitting glass OLEDs containing four independently addressable 5 mm×5 mm pixels were fabricated on patterned ITO coated glass (20 Ohm/sq, available from Delta Technologies Ltd., Stillwater Minn.) substrates by conventional thermal vapor deposition through shadow masks in a bell jar evaporator evacuated to 5×10⁻⁶ torr. The OLED device layers deposited on top of the patterned ITO anodes were (in order of deposition): MTDATA doped with FTCNQ (2.8% doping, 3000 Å at 1.8 Å/s)/NPD (400 Å at 1 Å/s)/AlQ doped with C545T (1% doping, 300 Å at 1 Å/s)/AlQ (200 Å at 1 Å/s)/LiF (7 Å at 0.5 Å/s)/Al (2500 Å at 25 Å/s).

An unencapsulated glass four pixel bottom emitting green OLED device was placed in the DLF batch coater described above and shown in FIG. 7 (OLED coated side facing up) and held to the electrode with strips of 3M Scotch™ 811 removable tape along each edge of the device as shown in FIG. 8. The schematic illustrates, with the construction shown in FIG. 8, tape 462 and 464, an ITO cathode pad 466, a cathode 468, an organic electronic device 470, an ITO anode 472, a device substrate 474, and a DLF electrode 476. The tape (462 and 464) prevents device movement during DLF deposition and serves as a mask to prevent DLF deposition over portions of the ITO cathode and anode leads, thereby allowing for electrical contact after encapsulation.

The system, the device shown in FIG. 8 in the chamber shown in FIG. 7, was pumped to base pressure (below about 1×10⁻³ Torr) and oxygen gas was introduced at a flow rate of 250 sccm. The sample surface was primed by a 10 second exposure to oxygen plasma (200 watt RF power). Tetramethylsilane gas was then introduced (50 sccm) while maintaining the oxygen flow at 250 sccm. A plasma was struck at 200 watts for 5 minutes to provide a diamond-like film on the OLED device that was approximately 500 nm thick. After removal from the DLF chamber, a nearly colorless optically uniform diamond-like film could be seen on the top surface of the device when viewing the device from an angle. Other than this film, the OLED device was visibly unchanged by the deposition process. When biased at about 9 volts, the light emission from each pixel was essentially identical to the emission prior to the DLF deposition. After three months exposure to ambient air in an office environment, all four pixels showed light emission very similar to that observed immediately after DLF deposition. Some small dark spots induced by exposure to air prior to the DLF deposition did not show any significant growth in the three month observation period. Additionally, little or no pixel shrinkage was observed.

### EXAMPLE 2

Top emitting OLEDs containing four independently addressable 5 mm×5 mm pixels were fabricated on ultrabarrier substrates by conventional thermal vapor deposition through shadow masks in a bell jar evaporator evacuated to 5×10⁻⁶ torr. Reflective anodes were first created by depositing Cr (100 Å at 1 Å/s) followed by Ag (1000 Å at 1 Å/s). The OLED device layers deposited on top of the Cr/Ag anodes were (in order of deposition): MTDATA doped with FTCNQ (2.8% doping, 3000 Å at 1.8 Å/s)/NPD (400 Å at 1 Å/s)/AlQ doped with C545T (1% doping, 300 Å at 1 Å/s)/AlQ (200 Å at 1 Å/s)/LiF(7 Å at 0.5 Å/s)/Al(50 Å at 5 Å/s)/Ag(200 Å at 1 Å/s).

An four pixel top emitting green OLED on an ultrabarrier substrate film, such as those described above, was encapsulated by laminating a second ultrabarrier film over the pixel area using pressure-sensitive adhesive (PSA) transfer adhesive film (3M 8141 Optical Adhesive). The ultrabarrier layers faced the OLED device structure. The device was placed in the DLF chamber in the same manner as described in Example 1. The system was pumped to base pressure (below about 1×10⁻³ Torr) and oxygen gas was introduced at a flow rate of 250 sccm. The sample surface was primed by a 10 second exposure to an oxygen plasma (200 watt RF power). Tetramethylsilane gas was then introduced (50 sccm) while maintaining the oxygen flow at 250 sccm. A plasma was struck at 200 watts for 5 minutes to provide a diamond-like film on the OLED device that was approximately 500 nm thick. After removal from the DLF chamber, a nearly colorless optically uniform diamond-like film could be seen on the top surface of the device when viewing the device from an angle. Some crack-like defects and some delamination of the metallic anode and cathode leads were observed where the DLF was deposited directly onto the leads. In the area of the device covered by the laminated ultrabarrier encapsulation film, no visible change, other than the barely visible diamond-like film, was detected after the DLF deposition. When biased at about 9 volts, the light emission from each pixel was essentially identical to the emission prior to the DLF deposition.

### EXAMPLE 3

A square (approximately 35 mm) piece of ultrabarrier film was laminated to the center of a larger square (approximately 50 mm) of ultrabarrier film using a square (approximately 35 mm) gasket of PSA transfer adhesive film (3M 8141 Optical Adhesive). The ultrabarrier layers faced each other. The width of the gasket was approximately 5 mm which left a square (approximately 25 mm) cavity between the two ultrabarrier films. The construction was placed in the DLF chamber in the same manner as described in Example 1 with the surface bearing the smaller ultrabarrier film facing upwards. The system was pumped to base pressure (below about 1×10⁻³ Torr) and oxygen gas was introduced at a flow rate of 250 sccm. The sample surface was primed by a 10 second exposure to an oxygen plasma (200 watt RF power). Tetramethylsilane gas was then introduced (50 sccm) while maintaining the oxygen flow at 250 sccm. A plasma was struck at 200 watts for 5 minutes to provide a diamond-like film on the film construction that was approximately 500 nm thick. After removal from the DLF chamber, a nearly colorless optically uniform diamond-like film could be seen on the top surface of the construction. This DLF was seen most readily by viewing the device at an angle. The construction appeared otherwise unchanged by the DLF deposition process.

### EXAMPLE 4

ITO coated glass substrates (50×50×0.5 mm, 20 ohm/square) were obtained from Thin Film Devices, Inc., Anaheim, Calif. The substrates were cleaned by rubbing with a methanol soaked lint-free cloth (Vectra Alpha 10, Texwipe Co., LLC, Upper Saddle River, N.J.) followed by a 5 minute oxygen plasma treatment (full power and 5 psi oxygen, Plasma-Preen II-973, Plasmatic Systems, Inc., North Brunswick, N.J.). The substrates were transferred to a glove box (M. Braun, Germany) containing a thin film evaporator (Edwards 500, BOC Edwards, England). Four substrates were placed in the chamber over shadow masks incorporating two “L” shaped openings at opposite corners displaced 4 mm inwards from edge of 50×50 mm stainless steel mask. The openings were 4 mm wide and each leg of the “L” was 26 mm long. The chamber was evacuated to about 5×10⁻⁷ torr and 2000 Å of SiO was deposited at about 2 Å/sec from a Mo canoe type source (Lesker part # EVS 13005Mo, Clairton, Pa.). The substrate holder was rotated continuously during the deposition. The chamber was vented and the substrates were turned 90° with respect to the shadow masks. The chamber was evacuated to 5×10⁻⁷ torr and another 2000 Å of SiO was deposited as described above to give a square SiO gasket centered on the 50 mm substrate with an outside dimension of 42×42 mm, an inside dimension of 34×34 mm, and about 10 mm overlap of the SiO layers at the midpoint of each side.

The gasketed substrates were removed from the glove box and exposed to a 3-minute oxygen plasma (Plasma-Preen). An aqueous solution of polythiophene (1% solids, Baytron P 4083, Bayer, Leverkuesen, Germany) was spun coat onto the substrates at 2500 rpm for 30 seconds on a Laurell spin coater. The polythiophene around the edges of the substrate was removed to about the mid point of the SiO gasket by carefully wiping with a moistened cotton swab. The coated substrates were dried at 110° C. under a nitrogen flow for 30 minutes. They were then placed in a bell jar OLED fabrication chamber over shadow mask with a 38×38 mm opening centered in the 50 mm stainless steel mask. This placed the edges of the mask along the approximate centerlines of each side of the SiO gasket. The chamber was evacuated to about 5×10⁻⁶ torr. A 2000 Å thick buffer layer of MTDATA doped with about 6% FTCNQ was deposited at 1.8 Å/sec. A green small molecule organic stack was then deposited during the same pumpdown:

NPD (300 Å at 1 Å/sec), AlQ doped with 1% C545T (300 Å at 1 Å/sec), and AlQ (200 Å at 1 Å/sec). Vacuum was broken and the partial devices were transferred, via a vacuum desiccator to minimize air exposure, to a glove box that contained a thin film evaporation chamber (Edwards 500, BOC Edwards, England) for the thermal deposition of cathodes. AlQ (200 Å at about 1.6 Å/sec, from H. W. Sands Corp., Jupiter, Fla.), LiF (7 Å at about 0.5 Å/sec, from Alfa-Aesar Co., Ward Hill, Mass.), Al (150 Å at about 1.0 Å/sec, from Alfa-Aesar Co., Ward Hill, Mass.), and Ag (1,500 Å at about 2.5 Å/sec, from Alfa-Aesar Co., Ward Hill, Mass.) were sequentially deposited at about 8×10⁻⁷ torr onto the organic coated substrates through the same metal shadow mask as used for the organic depositions. After venting and removal from the deposition chamber, all four devices showed uniform emission of green light of substantial brightness when driven at 6 volts.

Two of the four above devices were placed in the glove box evaporation chamber over shadow masks containing a 26×42 mm rectangular opening situated 4 mm from the top and 4 mm from the left edge of the 50 mm metal mask. This allowed for deposition over almost ⅔ of the area described by the SiO gasket and OLED device. Silicon monoxide (1000 Å, about 1 Å/sec) was deposited at about 2×10⁻⁷ torr while the sample holder rotated. The chamber was vented and the SiO encapsulation mask was replaced with a mask containing a 30×20 mm opening centered in the 50 mm metal mask. The long axis of this mask was oriented perpendicular to the long axis of the SiO rectangle deposited in the previous step. Silver (1000 Å, about 1 Å/sec) was deposited at about 1×10⁻⁷ torr. A portion of the silver layer was in direct contact with the device cathode while another portion was disposed on top of the SiO layer deposited in the previous step. The chamber was vented and the Ag cathode lead mask was replaced with the SiO encapsulation mask that was rotated 180° from its position for the first SiO encapsulation layer deposition. Silicon monoxide (1000 Å, about 1 Å/sec) was deposited at about 4×10⁻⁷ torr while the sample holder rotated. This SiO layer covered the remaining exposed area of the OLED, a portion of the Ag cathode lead, and a portion of the first SiO encapsulation layer thereby completely encapsulating the device while providing a conductive path to the device cathode. When driven at 6 volts DC by contacting the ITO anode along the edge of the device and the Ag cathode lead, the device emitted light in essentially the same manner as prior to the SiO and Ag encapsulation depositions.

1. A composite assembly for protection of a moisture or oxygen sensitive article, comprising:
a substrate;
an organic electronic device overcoated on the substrate; and
a diamond-like film layer overcoated on the organic electronic device.

2. The assembly of claim 1, further comprising a polymer layer located between the organic electronic device and the diamond-like film layer.

3. The assembly of claim 1, wherein the substrate comprises a rigid material or a flexible material.

4. The assembly of claim 1, wherein the diamond-like film layer comprises an at least substantially amorphous glass including carbon and silicon.

5. The assembly of claim 1 wherein the diamond-like film layer comprises an oxygen depleted layer having an oxygen to silicon ratio of less than approximately 1.5.

6. The assembly of claim 2, wherein the assembly has a plurality of a dyads overcoated on the substrate and wherein each dyad comprises the polymer layer overcoated with the diamond-like film layer.

7. The assembly of claim 1, further comprising:
an anode; and
a cathode,
wherein the organic electronic device is located between the anode and the cathode.

8. The assembly of claim 2, further comprising an adhesive located between the organic electronic device and the polymer layer.

9. The assembly of claim 1, further comprising another diamond-like film layer overcoated on the substrate on a side of the substrate opposite the organic electronic device.

10. The assembly of claim 1, wherein the substrate comprises a barrier.

11. The assembly of claim 1, wherein the substrate does not comprises a barrier and wherein the diamond-like film layer is overcoated on a side of the substrate opposite the organic electronic device.

12. The assembly of claim 1, wherein the an organic electronic device comprises one of the following: a bottom emitting organic light emitting diode, a top emitting organic light emitting diode, an organic photovoltaic device, or an organic transistor.

13. The assembly of claim 1, further comprising a stress relief layer located proximate the diamond-like film layer.

14. The assembly of claim 1, further comprising electrical contacts connected to the organic electronic device and interleaved between layers of the diamond-like film.

15. A process for fabricating a composite assembly for protection of a moisture or oxygen sensitive article, comprising:
providing a substrate;
overcoating an organic electronic device on the substrate; and
overcoating a diamond-like film layer on the organic electronic device.

16. The process of claim 15, further comprising overcoating a polymer layer on the organic electronic device before overcoating the diamond-like film layer.

17. The process of claim 15, wherein the step of overcoating the diamond-like film layer comprises overcoating an at least substantially amorphous glass including carbon and silicon.

18. The process of claim 15, wherein the step of overcoating the diamond-like film layer comprises overcoating an oxygen depleted layer having an oxygen to silicon ratio of less than approximately 1.5.

19. The process of claim 15, wherein the step of overcoating the organic electronic device comprises overcoating one of the following: a bottom emitting organic light emitting diode, a top emitting organic light emitting diode, an organic photovoltaic device, or an organic transistor.

20. A composite assembly for protection of a moisture or oxygen sensitive article, comprising:
a substrate;
an organic electronic device overcoated on the substrate;
an encapsulating film layer comprising an adhesive overcoated on the organic electronic device and having edges contacting the substrate; and
a diamond-like film layer overcoated on the encapsulating film layer, wherein the diamond-like film layer seals the edges of the adhesive in contact with the substrate.

21. The assembly of claim 20, wherein the an organic electronic device comprises one of the following: a bottom emitting organic light emitting diode, a top emitting organic light emitting diode, an organic photovoltaic device, or an organic transistor.

22. The assembly of claim 20, wherein the substrate comprises a rigid material or a flexible material.

23. The assembly of claim 20, wherein the encapsulating film comprises one of the following: a barrier, an optical film, or a structured film.

24. The assembly of claim 20, further comprising a stress relief layer located proximate the diamond-like film layer.
